(19) United States
(12) Patent Application Publication
(10) Pub. No.: US 2026/0182178 A1
(43) Pub. Date: Jun. 25, 2026

(54) DISPLAY APPARATUS

(71) Applicant: LG Display Co., Ltd., Seoul (KR)

(72) Inventor: CheolSe KIM, Paju-si (KR)

(73) Assignee: LG Display Co., Ltd., Seoul (KR)

(21) Appl. No.: 19/193,240

(22) Filed: Apr. 29, 2025

(30) Foreign Application Priority Data
Dec. 20, 2024 (KR) 10-2024-0192869

(51) Int. Cl. H10K 59/131; G06F 3/041; G06F 3/044; G09G 3/32; H10K 59/40

(52) U.S. Cl. CPC H10K 59/131; G06F 3/0412; G06F 3/04164; G06F 3/04166; G09G 3/32; H10K 59/40; G06F 3/0446; G09G 2300/0842; G09G 2330/021; G09G 2352/00

(57) ABSTRACT

A display apparatus in some examples includes a substrate having a display area, a pixel circuit layer including a plurality of pixel circuits disposed at the display area, an overcoat layer covering the pixel circuit layer, and a light emitting device layer disposed on the overcoat layer and connected to the plurality of pixel circuits. The light emitting device layer includes a plurality of anode electrodes connected to the plurality of pixel circuits, a light emitting portion disposed on the plurality of anode electrodes, and a cathode electrode connected to the light emitting portion. The pixel circuit layer includes a plurality of gate lines, a plurality of data lines, and a plurality of pixel driving voltage lines which are connected to corresponding pixel circuits, and a plurality of first touch lines and a plurality of second touch lines which are connected to the cathode electrode.

### CROSS-REFERENCE TO RELATED APPLICATION

This application claims priority to Korean Patent Application No. 10-2024-0192869 filed in the Republic of Korea on Dec. 20, 2024, the entirety of which is hereby expressly incorporated by reference into the present application.

### BACKGROUND

### Technical Field

The present disclosure relates to a display apparatus, and more specifically, to a display apparatus capable of touch sensing.

### Description of the Related Art

Display apparatuses are applied to various electronic devices such as TVs, mobile phones, smart watches, laptops, and tablets or the like.

The display apparatuses include organic light emitting display apparatuses that emit light by itself and liquid crystal display apparatuses which require a separate light source, or the like.

The display apparatuses provide a touch interface using a touch panel for convenience of a user input. The display apparatuses capable of touch interface processing are advancing to provide more various functions. For example, a display apparatuses with touch screen added therein, which are capable of finger touch sensing based on a finger as well as touch sensing based on a touch pen (or a stylus pen), are being widely used.

However, the display apparatuses having a touch panel becomes thick due to the thickness of the touch panel, and an improved process of placing the touch panel on the display panel is desired.

### SUMMARY OF THE DISCLOSURE

One or more aspects of the present disclosure are directed to providing a display apparatus capable of sensing a user touch.

One or more aspects of the present disclosure are directed to providing a display apparatus capable of sensing a user touch through an in-cell touch structure and having a thin thickness.

Additional features, advantages, and aspects of the present disclosure are set forth in part in the present disclosure and will also be apparent from the present disclosure or can be learned by practice of the inventive concepts provided herein. Other features, advantages, and aspects of the present disclosure can be realized and attained by the descriptions provided in the present disclosure, or derivable therefrom, and claims hereof as well as the appended drawings.

To achieve these and other advantages and aspects of the present disclosure, as embodied and broadly described herein, in one or more aspects, a display apparatus includes a substrate having a display area and a non-display area surrounding the display area, a pixel circuit layer including a plurality of pixel circuits disposed at the display area of the substrate, an overcoat layer covering the pixel circuit layer, and a light emitting device layer disposed on the overcoat layer and connected to the plurality of pixel circuits. The light emitting device layer comprises a plurality of anode electrodes disposed on the overcoat layer and connected to the plurality of pixel circuits, a light emitting portion disposed on the plurality of anode electrodes, and a cathode electrode disposed in the display area and electrically connected to the light emitting portion. The pixel circuit layer comprises a plurality of gate lines disposed in a first direction on the substrate and connected to corresponding pixel circuits of the plurality of pixel circuits, a plurality of data lines disposed in a second direction intersecting the first direction on the substrate and connected to corresponding pixel circuits of the plurality of pixel circuits, a plurality of pixel driving voltage lines disposed in the second direction on the substrate and connected to corresponding pixel circuits of the plurality of pixel circuits, a plurality of first touch lines disposed in the first direction on the substrate and electrically connected to the cathode electrode, and a plurality of second touch lines disposed in the second direction on the substrate and electrically connected to the cathode electrode.

Details of other example embodiments will be included in the detailed description of the disclosure and the accompanying drawings.

The display apparatus according to one or more embodiments of the present disclosure can sense a user touch.

The display apparatus according to one or more embodiments of the present disclosure can have a thin thickness because a separate touch panel is not attached due to the in-cell touch structure.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are examples and explanatory and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure and together with the description serve to explain principles of the disclosure.

FIG. 1 illustrates a display apparatus according to one or more embodiments of the present disclosure.

FIG. 2 is an equivalent circuit diagram illustrating a pixel shown in FIG. 1.

FIG. 3 is a cross-sectional view illustrating the cross-sectional structure of a sub-pixel according to an embodiment of the present disclosure.

FIG. 4 is a diagram illustrating an arrangement structure of a plurality of first touch lines and a plurality of second touch lines according to an embodiment of the present disclosure.

FIG. 5 is a cross-sectional view taken along line I-I′ illustrated in FIG. 4.

FIG. 6 is another example of a cross-sectional view taken along line I-I′ illustrated in FIG. 4.

FIG. 7 is a cross-sectional view taken along line II-II′ illustrated in FIG. 4.

FIG. 8 is another example of a cross-sectional view taken along line II-II′ illustrated in FIG. 4.

FIG. 9 is a diagram illustrating a display driving period and a touch driving period of a display apparatus according to an embodiment of the present disclosure.

FIG. 10 is a diagram illustrating a data driving integrated circuit, a timing control part, and a power generating integrated circuit illustrated in FIG. 1.

FIG. 11 is a diagram illustrating an example of a touch driving circuit illustrated in FIG. 10.

FIG. 12 is a diagram illustrating a touch sensing method in a display apparatus according to an embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof can be exaggerated for clarity, illustration, and convenience.

### DETAILED DESCRIPTION OF THE EMBODIMENTS

Advantages and features of the present disclosure, and implementation methods thereof, are clarified through the aspects described with reference to the accompanying drawings. The present disclosure may, however, be embodied in different forms and should not be construed as limited to the example aspects set forth herein. Rather, these example aspects are examples and are provided so that this disclosure can be thorough and complete to assist those skilled in the art to understand the inventive concepts without limiting the protected scope of the present disclosure.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted or briefly provided.

In a situation where “comprise,” “have,” and “include” described in the present disclosure are used, another part can be added unless “only” is used. The terms of a singular form can include plural forms unless referred to the contrary. Further, the term “can” fully encompasses all the meanings and coverages of the term “may” and vice versa.

In construing an element, the element is construed as including an error range although there is no explicit description.

In describing a position relationship, for example, when a position relation between two parts is described as “on,” “over,” “under,” and “next,” one or more other parts can be disposed between the two parts unless ‘just’ or ‘direct’ is used.

For the expression that an element is “connected,” “coupled,” or “contact,” to another element, the element may not only be directly connected, coupled, or contacted to another element, but also be indirectly connected, coupled, or contacted to another element with one or more intervening elements interposed between the elements, unless otherwise specified.

For the expression that an element is “contacts” or “overlaps” with another element, the element can not only directly contact, overlap, or the like with another element, but also indirectly contact or overlap with another element with one or more intervening elements disposed or interposed between the elements, unless otherwise specified.

Further, “a first direction,” “a second direction,” “a third direction,” “X-axis direction,” “Y-axis direction,” and “Z-axis direction” should not be construed by a geometric relation only of a mutual vertical relation and can have broader directionality within the range that elements of the present disclosure can act functionally.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in co-dependent relationship.

Hereinafter, example embodiments of a display apparatus according to the present disclosure will be described in detail with reference to the accompanying drawings. Al the components of each display apparatus according to all embodiments of the present disclosure are operatively coupled and configured. For convenience of description, a scale of each of elements illustrated in the accompanying drawings differs from a real scale, and thus, is not limited to a scale illustrated in the drawings.

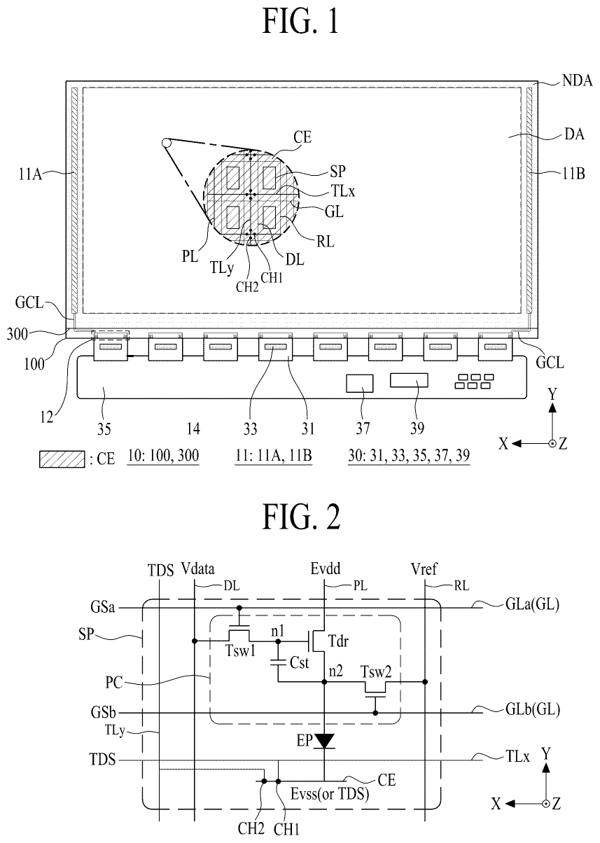

FIG. 1 illustrates a display apparatus according to one or more embodiments of the present disclosure, and FIG. 2 is an equivalent circuit diagram illustrating a pixel illustrated in FIG. 1.

Referring to FIGS. 1 and 2, a display apparatus according to one or more embodiments of the present disclosure can include a display panel 10 and a driving circuit part 30.

The display panel 10 can include a substrate 100 and an opposite substrate 300 bonded to each other.

The substrate 100 includes a thin film transistor, and the substrate 100 can be a transistor array substrate, a lower substrate, a base substrate, or a first substrate. The substrate 100 can include a display area DA (or active area) and a non-display area NDA (or non-active area). The display area DA is an area for displaying an image, and the display area DA can be a pixel array area, an active area, a pixel array part, a display part, or a screen. The non-display area NDA is an area in which an image is not displayed, and the non-display area NDA can be a peripheral circuit area, a signal supply area, a non-active area, or a bezel area. The non-display area NDA can be configured to surround the display area DA. The non-display area NDA can be disposed along an edge portion of the display panel 10. The non-display area NDA can include a pad area. The pad area, which is part of the non-display area, can be exposed externally without being covered by the opposing substrate 300 of the non-display area NDA.

The display panel 10 or the substrate 100 can include pixel driving lines, a plurality of sub-pixels SP, a gate driving circuit 11, a plurality of pad portions 12, and a plurality of link portions 13.

The pixel driving lines can include a plurality of gate lines GL, a plurality of data lines DL, a plurality of pixel driving voltage lines PL, a plurality of first touch lines TLx, and a plurality of second metal lines TLx which are disposed (or configured) in the display area DA. The pixel driving lines can further include a plurality of reference lines RL disposed parallel to the plurality of data lines DL, but the plurality of reference lines RL can be omitted. For example, the plurality of gate lines GL and the plurality of data lines DL can be disposed to define each of a plurality of sub-pixel areas.

Each of the plurality of sub-pixels SP can be disposed at each sub-pixel area which is defined by the pixel driving lines. One sub-pixel SP can be defined as a minimum unit area in which light is actually emitted.

Each of the plurality of sub-pixels SP according to an embodiment of the present disclosure can include a pixel circuit PC and a light emitting portion EP.

The plurality of gate lines GL can be disposed along a first direction X on the substrate 100 and can be connected to a corresponding pixel circuit PC of a plurality of pixel circuits PC. For example, the first direction X can be a long-side lengthwise direction of the substrate 100 or an X-axis direction.

The plurality of data lines DL can be disposed along a second direction Y intersecting the first direction X on the substrate 100 and can be connected to a corresponding pixel circuit PC of the plurality of pixel circuits PC. For example, the second direction Y can be a short-side lengthwise direction of the substrate 100 or a Y-axis direction.

The plurality of pixel driving voltage lines PL can be disposed in parallel with the plurality of data lines DL and can be connected to a corresponding pixel circuit PC of the plurality of pixel circuits PC. For example, the plurality of pixel driving voltage lines PL can be connected to pixel circuits PC disposed in each of three adjacent subpixels SP of the plurality of subpixels SP, but is not limited thereto.

The pixel circuit PC can include a first switching thin film transistor Tsw1, a second switching thin film transistor Tsw2, a driving thin film transistor Tdr, and a capacitor Cst. The thin film transistors Tsw1, Tsw2, and Tdr can be N-type thin film transistors (TFT), but is not limited thereto.

At least one of the first switching thin film transistor Tsw1, the second switching thin film transistor Tsw2, and the driving thin film transistor Tdr can include a semiconductor layer (or an active layer) based on any one of amorphous silicon, polycrystalline silicon, oxide, and organic material.

The first switching thin film transistor Tsw1 can be configured to supply a data voltage, which is supplied to the data line DL according to a first gate signal GSa having a gate-on voltage level supplied to a first gate line GLa of the gate line GL, to the first node n1, for example, a gate electrode of the driving thin film transistor Tdr.

The second switching thin film transistor Tsw2 can be configured to supply a reference voltage Vref, which is supplied to the reference line RL according to a second gate signal GSb having a gate-on voltage level supplied to a second gate line GLb of the gate line GL, to the second node n2, for example, a source electrode of the driving thin film transistor Tdr.

The capacitor Cst can be formed (or provided) between the gate electrode of the driving thin film transistor Tdr and the source electrode of the driving thin film transistor Tdr. The capacitor Cst can charge a differential voltage between the gate electrode of the driving thin film transistor Tdr and the source electrode of the driving thin film transistor Tdr, and then switch the driving thin film transistor Tdr according to the charged voltage.

The driving thin film transistor Tdr can be configured to control an amount of current flowing from the pixel driving voltage lines PL to the light emitting portion EP by being turned-on by a voltage of the capacitor Cst.

The light emitting portion EP can be configured to emit light by a current flowing from a driving thin film transistor Tdr of the pixel circuit PC to a cathode electrode CE. The light emitting portion EP according to an embodiment can be a self-emitting portion, a light emission portion, a spot light source portion, a light emitting device, a light emitting diode, a micro light emitting device, or a micro light emitting diode.

The cathode electrode CE can be disposed (or configured) in the display area DA. The cathode electrode CE can be disposed (or configured) on an entire display area DA.

The pixel driving lines can further include a plurality of first touch lines TLx and a plurality of second touch lines TLy disposed (or configured) in the display area DA.

The plurality of first touch lines TLx and the plurality of second touch lines TLy can be disposed to overlap with the cathode electrode CE or can be disposed under the cathode electrode CE.

The plurality of first touch lines TLx can be disposed in a first direction X on the substrate 100 and can be electrically connected to the cathode electrode CE. For example, each of the plurality of first touch lines TLx can be electrically connected to the cathode electrode CE through one or more first line contact holes CH1. For example, the plurality of first touch lines TLx can be parallel to the gate lines GL.

The plurality of second touch lines TLy can be disposed in a second direction Y on the substrate 100 and can be electrically connected to the cathode electrode CE. For example, each of the plurality of second touch lines TLy can be electrically connected to the cathode electrode CE through one or more second line contact holes CH2. For example, the plurality of second touch lines TLy can be parallel to the data lines DL.

The plurality of first touch lines TLx and the plurality of second touch lines TLy electrically connected to the cathode electrode CE can have a mesh shape.

According to an embodiment, the plurality of first touch lines TLx can be composed of a same material as the plurality of gate lines GL. For example, the plurality of first touch lines TLx can be disposed on a same layer as the plurality of gate lines GL.

According to an embodiment, the plurality of second touch lines TLy can be composed of a same material as the plurality of data lines DL, but is not limited thereto. For example, the plurality of second touch lines TLy can be composed of a different material than the plurality of data lines DL.

According to an embodiment, the plurality of second touch lines TLy can be disposed on a same layer as the plurality of data lines DL, but is not limited thereto. For example, the plurality of second touch lines TLy can be disposed on a different layer from the plurality of data lines DL.

The gate driving circuit 11 can be configured to supply gate signals GSa and GSb in a predetermined sequence to the plurality of gate lines GL disposed in the display area DA. For example, the gate driving circuit 11 can include a first gate driving circuit 11A and a second gate driving circuit 11B.

The first gate driving circuit 11A can be disposed at a first non-display area of the display area DA so as to be electrically connected to one end of each of the plurality of gate lines GL. The second gate driving circuit 11B can be disposed at a second non-display area so as to be electrically connected to the other end of each of the plurality of gate lines GL.

The gate driving circuit 11 (or the first and second gate driving circuits 11A and 11B can be directly formed or implemented on the substrate 100 through a manufacturing process of the thin-film transistors of the sub-pixels SP according to the GIP (Gate In Panel) method. For example, the gate driving circuit 11 (or the first and second gate driving circuits 11A and 11B can be a gate built-in (or embedded) circuit or a gate shift register circuit, but is not limited thereto.

The plurality of pad portions 12 can be disposed at the non-display area NDA so as to be spaced apart from each other along the first direction X.

Each of the plurality of pad portions 12 can include a plurality of data pads, a plurality of pixel driving voltage pads, a plurality of first touch line pads, and a plurality of second touch line pads. A first pad portion connected to a first data line of the plurality of pad portions 12 can further include a plurality of gate pads. In addition, A last pad portion connected to a last data line of the plurality of pad portions 12 can further include a plurality of gate pads. Each of the plurality of pad portions 12 can further include a plurality of reference voltage pads.

The plurality of data pads can be connected to the plurality of data lines DL through a plurality of data link lines. The plurality of pixel driving voltage pads can be connected to the plurality of pixel driving voltage lines PL through a plurality of driving voltage link lines. The plurality of reference voltage pads can be connected to the plurality of reference lines RL through a plurality of reference link lines. The plurality of first touch line pads can be connected to the plurality of first touch lines TLx through a plurality of first touch link lines. The plurality of second touch line pads can be connected to the plurality of second touch lines TLy through a plurality of second touch link lines.

Each of the plurality of gate pads can be electrically connected to the gate driving circuit 11 through each of a plurality of gate control lines GCL. For example, the plurality of gate pads disposed at the first pad portion can be electrically connected to the first gate driving circuit 11A through the plurality of gate control lines GCL, and the plurality of gate pads disposed at the last pad portion can be electrically connected to the second gate driving circuit 11B through the plurality of gate control lines GCL.

The opposite substrate 300 can be bonded to face the substrate 100 by using an adhesive member (or transparent adhesive). For example, the opposite substrate 300 can have a smaller size than the substrate 100 and can be bonded to face the remaining portion of the substrate 100 except for the pad portion 12. The opposite substrate 300 can be an upper substrate, a second substrate, an encapsulation substrate, or a color filter substrate. The opposite substrate 300 can be bonded to a first surface of the substrate 100 by a substrate bonding process using the adhesive member.

The driving circuit part (or a panel driving circuit) 30 can be connected to a plurality of pad portions 12 of the display panel 10 (or substrate 100). The driving circuit part 30 can drive (or emit light) the plurality of sub-pixels SP disposed at the display area DA based on image data supplied from a host driving system (or host control part), thereby displaying an image corresponding to the image data in the display area DA. In addition, the driving circuit part 30 can be configured to sense a user touch through each of the plurality of first touch lines TLx and the plurality of second touch lines TLy. For example, the driving circuit part 30 can be configured to drive (or emit light) the plurality of sub-pixels SP in a display driving period (or display driving mode) to display an image corresponding to the image data in the display area DA. For example, the driving circuit part 30 can be configured to sense current flowing in each of the plurality of first touch lines TLx and the plurality of second touch lines TLy to determine whether a touch is present or to determine touch coordinates, in a touch driving period (or a touch sensing period or a touch sensing mode).

The driving circuit part 30 according to an embodiment can include a plurality of circuit films 31, a plurality of data driving integrated circuits 33, a printed circuit board 35, a timing control part 37, and a power generating integrated circuit 39.

Each of the plurality of circuit films 31 can be attached to the printed circuit board 35 by a film attachment process using an anisotropic conductive film, and can be attached to each of the plurality of pad portions 12 configured on the substrate 100 by a film attachment process using an anisotropic conductive film. Each of the plurality of circuit films 31 can be bent or folded toward a rear surface of the substrate 100 so as to around a side surface of the substrate 100.

Each of the plurality of data driving integrated circuits 33 can be individually mounted on each of the plurality of circuit films 31. For example, the circuit film 31 and the data driving integrated circuits 33 can be expressed as a data driving part, but is not limited thereto.

Each of the plurality of data driving integrated circuits 33 can receive pixel data and a data control signal provided from a timing control part 37 in the display driving period, and can convert the pixel data into an analog pixel-based data signal (or pixel-by-pixel analog data) according to the data control signal and supplies the analog pixel-based data signal to a corresponding data line.

Each of the plurality of data driving integrated circuits 33 can be configured to sense a user touch through each of the plurality of first touch lines TLx and each of the plurality of second touch lines TLy in the touch driving period. For example, each of the plurality of data driving integrated circuits 33 can be configured to sense current flowing through each of the plurality of first touch lines TLx and each of the plurality of second touch lines TLy to determine whether a touch is present or to determine touch coordinates, in the touch driving period.

The printed circuit board 35 can support the timing control part 37 and the power generating integrated circuit 39, and serves to transmit signals and power between the components of the driving circuit part 30. For example, the printed circuit board 35 can be disposed on the rear surface of the substrate 100.

The timing control part 37 can be mounted on the printed circuit board 35 and can receive image data and a timing synchronization signal provided from the host driving system through a user connector disposed at the printed circuit board 35. The timing control part 37 can be configured to drive the display panel 10 in the display driving period (or display mode) and the touch driving period (or touch sensing mode) based on the timing synchronization signal. For example, the timing control part 37 can time-divide one frame based on a vertical synchronization signal of the timing synchronization signal and can drive the display panel 10 in the display driving period and the touch driving period. For example, in one frame, the display driving period can be longer than the touch driving period. For example, the timing control part 37 can generate a touch synchronization signal that time-divides one frame into the display driving period and the touch driving period based on the timing synchronization signal. The timing control part 37 can drive each of the plurality of data driving integrated circuits 33 and gate driving circuits 11 (or the first and second gate driving circuits 11A and 11B in the display driving mode and the touch sensing mode according to the touch synchronization signal.

The timing control part 37 can align image data based on the timing synchronization signal to match a pixel arrangement structure of the display area DA to generate pixel data, and can provide the generated pixel data to the corresponding data driving integrated circuit 33. In addition, the timing control part 37 can generate the data control signal and the gate control signal based on the timing synchronization signal, can control the driving timing of each of a plurality of data driving integrated circuits 33 through the data control signal, and can control the driving timing of the first and second gate driving circuits 11A and 11B through the gate control signal.

The timing control part 37 according to an embodiment can control driving of the plurality of data driving integrated circuits 33 and the gate driving circuit 11 (or first and second gate driving circuits 11A and 11B) so that each of the plurality of gate lines GL and the plurality of data lines DL can be maintained in a high impedance state during the touch driving period. For example, the timing control part 37 can control driving of the plurality of data driving integrated circuits 33 and the gate driving circuit 11 (or first and second gate driving circuits 11A and 11B) so that each of the plurality of gate lines GL and the plurality of data lines DL is electrically floated in the touch driving period.

The power generating integrated circuit (or a power driving part or a power generating circuit) 39 can be configured to generate and output various powers for driving the display apparatus. For example, the power generating integrated circuit 39 can be configured to generate and output a pixel driving voltage Evdd, a reference voltage Vref, a cathode voltage Evss, and logic power voltages or the like according to the control of the timing control part 37 based on input power.

The power generating integrated circuit 39 can output the cathode voltage Evss based on the input power in the display driving period according to the touch synchronization signal, and can output a touch driving signal TDS by modulating the cathode voltage Evss in the touch driving period according to the touch synchronization signal. For example, the cathode voltage Evss or the touch driving signal TDS output from the power generating integrated circuit 39 in the display driving period can be supplied to the cathode electrode CE through the plurality of data driving integrated circuits 33, the plurality of first touch lines TLx and the plurality of second touch lines TLy. For example, the touch driving signal TDS can include a plurality of touch driving pulses having an amplitude between a low voltage and a high voltage.

Furthermore, the power generating integrated circuit 39 can output a load reduction signal (or a load free driving signal) having a same frequency and a same voltage width (or voltage amplitude) as the touch driving signal TDS in the touch driving period based on the touch synchronization signal. The gate driving circuit 11 (or the first and second gate driving circuits 11A and 11B according to another embodiment can be configured to simultaneously supply the load reduction signal to all gate lines GL in the touch driving period based on the touch synchronization signal. Each of the plurality of data driving integrated circuits 33 according to another embodiment can be configured to simultaneously supply the load reduction signal to all data lines DL and all pixel driving voltage lines PL in the touch driving period based on the touch synchronization signal. Each of the plurality of data driving integrated circuits 33 according to another embodiment can be configured to simultaneously supply the load reduction signal to all data lines DL, all pixel driving voltage lines PL, and all reference lines RL in the touch driving period based on the touch synchronization signal.

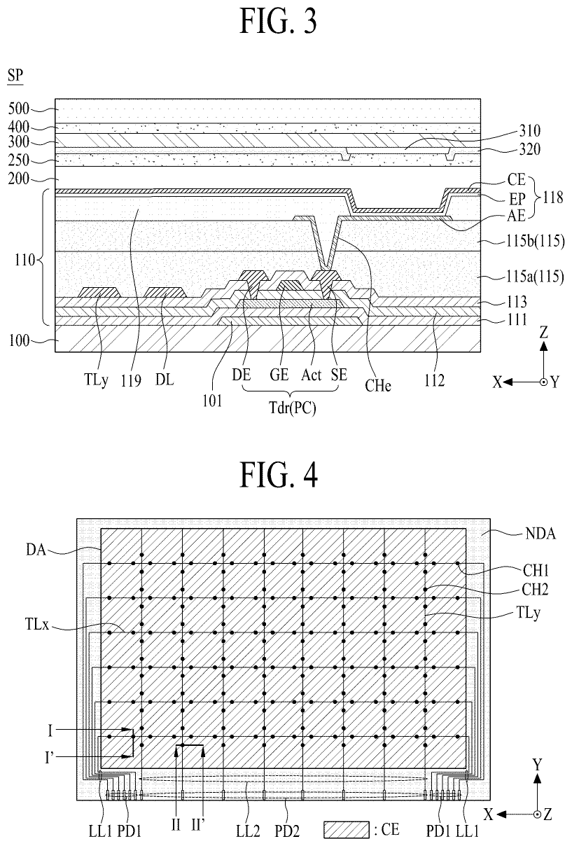

FIG. 3 is a cross-sectional view illustrating the cross-sectional structure of a sub-pixel according to an embodiment of the present disclosure.

Referring to FIGS. 2 and 3, a display panel 10 (or display apparatus) according to an embodiment of the present disclosure can include a substrate 100 and a pixel array layer 110.

The substrate 100 can be made of a glass material, but is not limited thereto. For example, the substrate 100 can include one or more plastic material layers.

The pixel array layer (or a pixel portion) 110 can include a pixel circuit layer. The pixel circuit layer can include a buffer layer 111, a plurality of pixel circuits PC, a plurality of first touch lines TLy, and a plurality of second touch lines TLy.

The buffer layer 111 can be disposed (or formed) on the substrate 100. The buffer layer 111 can serve to prevent materials contained in the substrate 100 from spreading to a transistor for a high-temperature step of a process for manufacturing a thin film transistor, or can serve to prevent external water or moisture from being permeated into a light emitting device layer 118.

Each of the plurality of pixel circuits PC can include a driving thin film transistor Tdr disposed in a sub-pixel area above the buffer layer 111.

The driving thin film transistor Tdr can include an active layer Act, a gate insulating film 112, a gate electrode GE, an interlayer insulating film 113, a drain electrode DE, and a source electrode SE.

The active layer Act can be disposed (or formed) on the buffer layer 111. For example, the active layer Act can include a semiconductor material based on a metal oxide such as indium-gallium-zinc-oxide IGZO or the like, but is not limited thereto, and can include a semiconductor material based on silicon such as amorphous silicon or polycrystalline silicon, or the like. For example, the active layer Act can be formed into a pattern shape (or an island shape) by depositing a semiconductor material on the buffer layer 111, performing a heat treatment process for stabilization, and a patterning process of the semiconductor material. The active layer Act can include a channel region, a drain region, and a source region. The channel region can be formed between the drain region and the source region.

The gate insulating film 112 can be formed in an island shape only on the channel region of the active layer Act or can be formed to cover an entire front surface of the buffer layer 110 including the active layer Act. For example, the gate insulating film 112 can be made of an inorganic material or an organic material.

The gate electrode GE can be disposed over the gate insulating film 112 so as to overlap with the channel region of the active layer Act. The gate electrode GE can be formed of a metal material. The gate electrode GE can be formed together with a plurality of gate lines GL. For example, the gate electrode GE and the plurality of gate lines GL can be formed simultaneously by patterning on a metal material layer.

The interlayer insulating film 113 can be formed over the gate electrode GE and the drain region and source region of the active layer Act. For example, the interlayer insulating film 113 can be made of an inorganic material or an organic material.

The drain electrode DE can be electrically connected to the drain region of the active layer Act through a drain contact hole provided in an interlayer insulating film 112 overlapping with the drain region of the active layer Act. The drain electrode DE can be electrically connected to a corresponding pixel driving voltage line PL among the plurality of pixel driving voltage lines PL through the electrode contact hole. Accordingly, the drain electrode DE of the driving thin film transistor Tdr can receive the pixel driving voltage Evdd through the pixel driving voltage line PL.

The source electrode SE can be electrically connected to the source region of the active layer Act through a source contact hole provided in an interlayer insulating film 113 overlapping with the source region of the active layer Act.

Each of the drain electrode DE and the source electrode SE can be formed of a same metal material. For example, each of the drain electrode DE and the source electrode SE can be formed of a single metal layer, a single layer of an alloy, or multiple layers of two or more layers, which are a same as or different from the gate electrode GE. The source electrode SE and the drain electrode DE can be formed together with the data line DL. For example, the source electrode SE, the drain electrode DE, and the plurality of data lines DL can be formed simultaneously by patterning a metal material layer. Additionally, the plurality of data lines DL can be formed simultaneously with the plurality of pixel driving voltage lines PL and the plurality of reference lines RL.

Each of the plurality of pixel circuits PC can further include first and second switching thin film transistors Tsw1 and Tsw2 formed (or disposed) together with the driving thin film transistor Tdr, and a capacitor Cst. Since each of the first and second switching thin film transistors Tsw1 and Tsw2 has a same structure as the driving thin film transistor Tdr, a description thereof will be omitted. The capacitor Cst can be provided in an overlapping region between the gate electrode GE and the source electrode SE of the driving thin film transistor Tdr which overlap each other with an interlayer insulating film 113 therebetween.

Additionally, the thin film transistor provided in each of the plurality of pixel circuits PC can have the properties related with a shift of a threshold voltage by light. To prevent this phenomenon, the display panel 10 or the substrate 100 can further include a light shielding pattern 101 provided below the active layer Act of at least one of the driving thin film transistor Tdr, the first switching thin film transistor Tsw1, and the second switching thin film transistor Tsw2. The light shielding pattern 101 can be formed (or disposed) on the substrate 100 so as to overlap with the active layer Act. For example, the light shielding pattern 101 can be covered by the buffer layer 111.

According to an embodiment, each of the plurality of first touch lines TLx can be formed together with the plurality of gate lines GL and can be electrically connected to the cathode electrode CE through the one or more first line contact holes CH1.

According to an embodiment, each of the plurality of second touch lines TLy can be formed together with the plurality of data lines DL and can be electrically connected to the cathode electrode CE through the one or more second line contact holes CH2, but is not limited thereto.

The pixel array layer 110 can further include an overcoat layer 115, a light emitting device layer 118, and a bank 119.

The overcoat layer 115 can be provided on the substrate 100 to cover the pixel circuit layer 110. The overcoat layer 115 can be implemented to planarize an upper portion of the pixel circuit PC and protect the pixel circuit PC. The overcoat layer 115 can be formed to cover the drain electrode DE and the source electrode SE of the driving thin film transistor Tdr, the interlayer insulating film 113, the pixel driving lines, the plurality of first touch lines TLx, and the plurality of second touch lines TLy. For example, the overcoat layer 115 can include a first overcoat layer 115a and a second overcoat layer 115b formed on the first overcoat layer 115a. The first overcoat layer 115a and the second overcoat layer 115b can have a same thickness or different thicknesses. The overcoat layer 115 (or the first and second overcoat layers 115a and 115b can be made of an organic material.

The light emitting device layer 118 can include an anode electrode AE, a light emitting portion EP, and a cathode electrode CE.

The anode electrode (or first electrode) AE can be formed (or deposited) in a pattern shape on the overcoat layer 115. The anode electrode AE can be formed (or deposited) on the second overcoat layer 115b of the overcoat layer 115. The anode electrode AE can be electrically connected to the source electrode SE of the driving thin film transistor TFT through an electrode contact hole CHe formed in the overcoat layer 115. For example, the anode electrode AE can be a reflective electrode that reflects light.

The light emitting portion (or light emitting device) EP can be formed (or deposited) on the anode electrode AE.

The light emitting portion EP according to an embodiment can have a white light emitting structure including two or more light emitting layers for emitting white light. As an example, the light emitting portion EP can include a first light emitting layer and a second light emitting layer to emit white light by a mixture of first light and second light. For example, the first light emitting layer can include any one of a blue light emitting layer, a green light emitting layer, a red light emitting layer, a yellow light emitting layer, and a yellow-green light emitting layer for emitting the first light. For example, the second light emitting layer can include a light emitting layer capable of emitting the second light so as to obtain white light in the light emitting portion EP by a mixture with the first light of a blue light emitting layer, a green light emitting layer, a red light emitting layer, a yellow light emitting layer, or a yellow-green light emitting layer.

The light emitting portion EP according to another embodiment can have an RGB light emitting structure including any one of the blue light emitting layer, the green light emitting layer, and the red light emitting layer. For example, when the sub-pixel SP is a red sub-pixel, the light emitting portion EP of the red sub-pixel can include the red light emitting layer. When the sub-pixel SP is a green sub-pixel, the light emitting portion EP of the green sub-pixel can include the green light emitting layer. In addition, when the sub-pixel SP is a blue sub-pixel, the light emitting portion EP of the blue sub-pixel can include the blue light-emitting layer.

The cathode electrode (or a second electrode) CE can be formed (or deposited) on the light emitting portion EP and can be in direct contact with the light emitting portion EP. The cathode electrode CE can be in common contact with (or connected to) the light emitting portions EP disposed in each of the plurality of sub-pixels SP. For example, the cathode electrode CE can be a transparent electrode that transmits light. The cathode electrode CE can be formed over an entire display area. The cathode electrode CE can overlap with each of the plurality of first touch lines TLx and the plurality of second touch lines TLy and can be electrically connected to the plurality of first touch lines TLx and the plurality of second touch lines TLy.

The bank 119 can be disposed to define an opening portion (or a light emitting area) of each of the plurality of sub-pixels SP and to cover an edge portion of the anode electrode AE formed in each of the plurality of sub-pixels SP. For example, the bank 119 can be disposed (or formed) on the overcoat layer 115 to cover only the edge portion excluding a center portion of the anode electrode AE. The bank 119 can be interposed between the overcoat layer 115 and the light emitting portion EP in a non-opening portion (or a non-light emitting area) of each of the plurality of sub-pixels SP. For example, the light emitting portion EP can be formed (or deposited) on the bank 119 in the non-opening portion (or non-light emitting area) of each of the plurality of sub-pixels SP. For example, the bank 119 can be formed of an organic material or an inorganic material and can include a light absorbing material including a black pigment.

The display panel 10 (or display apparatus) according to an embodiment of the present disclosure can further include an encapsulating layer 200 and a cover window 500.

The encapsulation layer 200 can be formed (or deposited) on the pixel array layer 110 and configured to cover the light emitting device layer 118. The encapsulation layer 200 can be configured to prevent oxygen or moisture from penetrating into the light emitting device layer 118. For example, the encapsulation layer 200 can include one or more inorganic encapsulation layers and one or more organic encapsulation layers over the light emitting device layer 118.

The cover window 500 can be implemented to cover an entire encapsulating layer 200. For example, the cover window 500 can be attached or coupled to the encapsulating layer 200 by using a connecting member 400. Thus, the cover window 500 can protect the light emitting device layer 118 from external impact or block impact applied to the light emitting device layer 118.

The display panel 10 (or display apparatus) according to an embodiment of the present disclosure can further include an opposite substrate (or a counter substrate) 300.

The opposite substrate 300 can be disposed (or interposed) between the encapsulating layer 200 and the cover window 500. The opposite substrate 300 can be a color filter substrate. For example, when the light emitting portion EP disposed in the sub-pixel SP has an RGB light emitting structure, the opposite substrate 300 can be omitted.

The opposite substrate 300 can include a color filter layer 310 and a black matrix 320.

The color filter layer 310 can be formed (or disposed) on the opposite substrate 300 so as to overlap with the opening portion of each of the plurality of sub-pixels SP. For example, the color filter layer 310 can include a color filter that transmits only the wavelength of the color set to the sub-pixel SP among the light emitted from the light emitting portion EP toward the cover window 500. For example, the color filter layer 310 can transmit only a red wavelength, a green wavelength, or a blue wavelength. For example, the color filter layer 310 can include a red color filter that overlaps with the opening portion of the red sub-pixel, a green color filter that overlaps with the opening portion of the green sub-pixel, and a blue color filter that overlaps with the opening portion of the blue sub-pixel.

The black matrix 320 can be disposed (or formed) between the color filters formed in the color filter layer 310. For example, the black matrix 320 can be formed to surround the color filters formed in the color filter layer 310. For example, the black matrix 320 can have an opening portion that overlaps with the color filters formed in the color filter layer 310.

The opposite substrate 300 can be attached or coupled to the encapsulating layer 200 by using an adhesive member 250.

The display panel 10 (or display apparatus) according to an embodiment of the present disclosure can further include an optical film. The optical film can further include a polarizing film disposed (or interposed) between the cover window 500 and the encapsulating layer 200. The polarizing film changes external light which is reflected by the thin film transistors and/or lines provided in the sub-pixel SP into a circularly polarized state to improve visibility and a contrast ratio of the light emitting display apparatus. For example, the optical film can be implemented as a circularly polarization film.

FIG. 4 is a diagram illustrating an arrangement structure of a plurality of first touch lines and a plurality of second touch lines according to an embodiment of the present disclosure.

Referring to FIGS. 1 and 4, the plurality of first touch lines TLx according to an embodiment of the present disclosure can extend along a first direction X and can be spaced apart from each other at predetermined intervals along a second direction Y. The plurality of first touch lines TLx can be used (or driven) as a first touch sensing line (or an X-axis touch sensing line). Each of the plurality of first touch lines TLx can be electrically connected to the cathode electrode CE through the one or more first line contact holes CH1. For example, each of the plurality of first touch lines TLx can be electrically connected to the cathode electrode CE through a plurality of first line contact holes CH1 having predetermined intervals along the first direction X. Accordingly, the plurality of first touch lines TLx can receive the cathode voltage in the display driving period and can receive a touch driving signal in the touch driving period.

The plurality of first touch lines TLx can be respectively connected to a plurality of first touch line pads PD1 disposed at the plurality of pad portions 12 through a plurality of first touch link lines (or first touch routing lines) LL1. For example, one end of each of the plurality of first touch lines TLx can be respectively connected to the plurality of first touch line pads PD1 disposed at the plurality of pad portions 12 through the plurality of first touch link lines LL1 passing through the non-display area NDA. The other end of each of the plurality of first touch lines TLx can be respectively connected to the plurality of first touch line pads PD1 disposed at the remaining pad portions among the plurality of pad portions 12 through the plurality of first touch link lines LL1 passing through the non-display area NDA.

The plurality of first touch line pads PD1 can be included in the first pad portion and the last pad portion among the plurality of pad portions 12, but is not limited thereto. For example, the plurality of first touch line pads PD1 can be distributed and disposed at the plurality of pad portions 12 based on an arrangement region of the plurality of first touch link lines LL1.

According to an embodiment of the present disclosure, the plurality of second touch lines TLy can extend along the second direction Y and be spaced apart at predetermined intervals along the first direction X. The plurality of second touch lines TLy can be used (or driven) as a second touch sensing line (or a Y-axis touch sensing line). Each of the plurality of second touch lines TLy can be electrically connected to the cathode electrode CE through the one or more second line contact holes CH2. For example, each of the plurality of second touch lines TLy can be electrically connected to the cathode electrode CE through a plurality of second line contact holes CH2 having predetermined intervals along the second direction Y. Accordingly, the plurality of second touch lines TLy can receive the cathode voltage in the display driving period and can receive the touch driving signal in the touch driving period.

The plurality of second touch lines TLy can be respectively connected to a plurality of second touch line pads PD2 disposed at the plurality of pad portions 12 through a plurality of first touch link lines LL2. For example, one end of each of the plurality of second touch lines TLy can be electrically connected to the plurality of second touch line pads PD2 disposed at some of the pad portions 12 through the plurality of first touch link lines LL2. For example, the plurality of second touch line pads PD2 can be distributed and disposed at the plurality of pad portions 12 based on an arrangement region of the plurality of second touch link lines LL2.

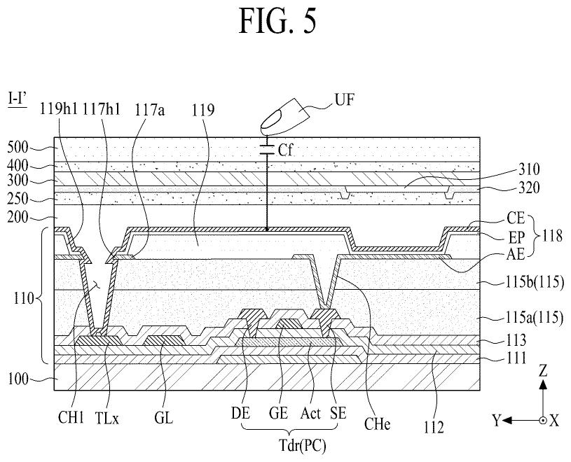

FIG. 5 is a cross-sectional view taken along line I-I′ illustrated in FIG. 4.

Particularly, FIG. 5 is a diagram illustrating an electrical connection structure of a plurality of first touch lines and a cathode electrode according to an embodiment of the present disclosure. In the following description, therefore, descriptions of the other elements except for the electrical connection structure of the plurality of first touch lines and the cathode electrode can be substantially a same as the description with reference to FIGS. 2 and 3, and thus, repeated descriptions thereof are omitted or briefly provided. Accordingly, the descriptions with reference to FIGS. 2 and 3 can be included in descriptions of FIG. 5.

Referring to FIGS. 4 and 5, each of the plurality of first touch lines TLx according to an embodiment of the present disclosure can be disposed on a same layer as the plurality of gate lines GL or can be made of a same material as the plurality of gate lines GL. The plurality of first touch lines TLx can be disposed parallel to the plurality of gate lines GL.

Each of the plurality of first touch lines TLx according to an embodiment can be formed (or disposed) at the gate insulating film 112 and covered by the interlayer insulating film 113. Each of the plurality of first touch lines TLx can be directly connected to the cathode electrode CE. For example, each of the plurality of first touch lines TLx can be electrically connected to the cathode electrode CE through the one or more first line contact holes CH1. The cathode electrode CE can be directly connected to each of the plurality of first touch lines TLx through the one or more first line contact holes CH1.

The one or more first line contact holes CH1 according to an embodiment can be formed to penetrate the overcoat layer 115 and the interlayer insulating film 113 to expose a portion of each of the plurality of first touch lines TLx. The one or more first line contact holes CH1 can be formed to penetrate the overcoat layer 115 and the interlayer insulating film 113 overlapping each of the plurality of first touch lines TLx. For example, the one or more first line contact holes CH1 can be formed by an etching process (or an over-etching process) on the overcoat layer 115 and the interlayer insulating film 113 using a first mask metal pattern 117a having one or more first hollow holes 117h1 as a mask. For example, the first mask metal pattern 117a can be formed (or disposed) together with the anode electrode AE on the overcoat layer 115 overlapping each of the plurality of first touch lines TLx.

The one or more first line contact holes CH1 can be formed by an etching process (or over-etching process) on the overcoat layer 115 and the interlayer insulating film 113 overlapping the one or more first hollow holes 117h1 of the first mask metal pattern 117a to penetrate the overcoat layer 115 and the interlayer insulating film 113. In addition, the bank 119 can include one or more first opening holes 119h1 overlapping the one or more first line contact holes CH1.

The light emitting portion EP formed (or deposited) on the one or more of the first line contact holes CH1 can be disconnected by an undercut region (or an eaves region) between each of the first mask metal patterns 117a and the overcoat layer 115 (or the second overcoat layer 115b). In addition, the cathode electrode CE formed (or deposited) on the one or more of the first line contact holes CH1 can be formed (or deposited) along the first opening hole 119h1 of the bank 119, the first hollow hole 117h1 of the first mask metal pattern 117a, and an inner surface (or sidewall) of the one or more of the first line contact holes CH1, thereby directly contacting (or connecting) each of the plurality of first touch lines TLx.

Accordingly, the cathode electrode CE can receive the cathode voltage through each of the plurality of first touch lines TLx in the display driving period and can receive the touch driving signal through each of the plurality of first touch lines TLx in the touch driving period.

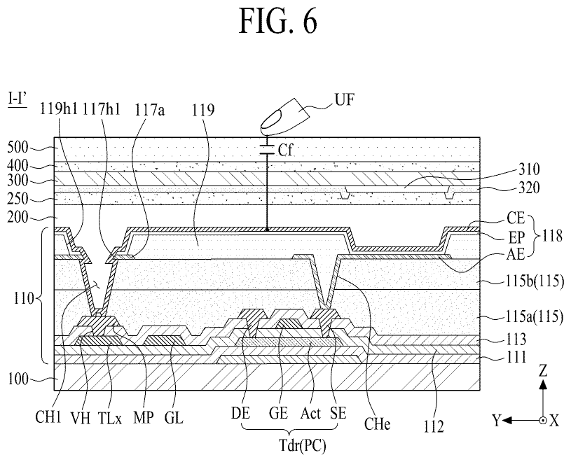

FIG. 6 is another cross-sectional view taken along line I-I′ illustrated in FIG. 4.

Particularly, FIG. 6 is a diagram illustrating an embodiment where one or more intermediate metal patterns are additionally configured between each of the plurality of first touch lines and the cathode electrode described above with reference to FIG. 5. In the following description, therefore, descriptions of the other elements except for the one or more intermediate metal patterns and relevant elements can be substantially a same as the description with reference to FIG. 5, and thus, repeated descriptions thereof are omitted or briefly provided. Accordingly, the descriptions with reference to FIG. 5 can be included in descriptions of FIG. 6.

Referring to FIGS. 4 and 6, each of the plurality of first touch lines TLx according to another embodiment of the present disclosure can be electrically (or indirectly) connected to the cathode electrode CE through one or more intermediate metal patterns MP.

The one or more intermediate metal patterns MP can be interposed (or disposed) between each of the plurality of first touch lines TLx and the cathode electrode CE. For example, the one or more intermediate metal patterns MP can be formed (or disposed) on the interlayer insulating film so as to overlap each of the plurality of first touch lines TLx and can be covered by the overcoat layer 115. For example, the one or more intermediate metal patterns MP can be disposed on a same layer as the plurality of data lines DL or can be made of a same material as the plurality of data lines DL.

The one or more intermediate metal patterns MP can be electrically connected to each of the plurality of first touch lines TLx through one or more via holes VH penetrating the interlayer insulating film 113.

The one or more intermediate metal patterns MP can be electrically connected to the cathode electrode CE through the one or more first line contact holes CH1. The cathode electrode CE can be connected to each of the plurality of first touch lines TLx through the one or more first line contact holes CH1, the one or more intermediate metal patterns MP, and the one or more via holes VH.

The one or more first line contact holes CH1 according to another embodiment can be formed to penetrate the overcoat layer 115 to expose a portion of the one or more intermediate metal patterns MP. The one or more first line contact holes CH1 can be formed to penetrate the overcoat layer 115 overlapping the one or more intermediate metal patterns MP. For example, the one or more first line contact holes CH1 can be formed by an etching process (or an over-etching process) on the overcoat layer 115 using a first mask metal pattern 117a having one or more first hollow holes 117h1 as a mask. For example, the first mask metal pattern 117a can be formed (or disposed) together with the anode electrode AE on the overcoat layer 115 overlapping each of the plurality of first touch lines TLx.

The one or more first line contact holes CH1 can be formed to penetrate the overcoat layer 115 by an etching process (or over-etching process) over the overcoat layer 115 overlapping the one or more first hollow holes 117h1 of the first mask metal pattern 117a. In addition, the bank 119 can include one or more opening holes overlapping the one or more first line contact holes CH1.

The light emitting portion EP formed (or deposited) on the one or more of the first line contact holes CH1 can be disconnected by an undercut region (or an eaves region) between each of the first mask metal patterns 117a and the overcoat layer 115 (or the second overcoat layer 115b). In addition, the cathode electrode CE formed (or deposited) on the one or more of the first line contact holes CH1 can be formed (or deposited) along the opening hole of the bank 119, the first hollow hole 117h1 of the first mask metal pattern 117a, and an inner surface (or sidewall) of the one or more of the first line contact holes CH1, thereby being connected to each of the plurality of first touch lines TLx through the one or more intermediate metal patterns MP and the one or more via holes VH. Therefore, the one or more intermediate metal patterns MP can prevent contact defect due to a distance between the first touch line TLx and the cathode electrode CE.

Accordingly, the cathode electrode CE can receive the cathode voltage through each of the plurality of first touch lines TLx and the one or more intermediate metal patterns MP in the display driving period, and can receive a touch driving signal through each of the plurality of first touch lines TLx and the one or more intermediate metal patterns MP in the touch driving period.

Referring to FIGS. 5 and 6, in a touch driving period, when the touch driving signal is applied to the plurality of first touch lines TLx and a user's finger UF is in direct contact (or touch) with the cover window 500, a finger capacitance Cf is formed between the user's finger UF and the cathode electrode CE, and as the finger capacitance Cf is formed, a current can be generated in a transition period of the first touch driving signal applied to the first touch lines TLx corresponding to a touch area of the user's finger UF and flow to the first touch line TLx close to the touch area of the user's finger UF. Accordingly, the driving circuit part can sense the current flowing through the first touch line TLx corresponding to the touch area of the user's finger UF and calculate an X-coordinate corresponding to a position of the first touch line TLx where the current is generated of the plurality of first touch lines TLx.

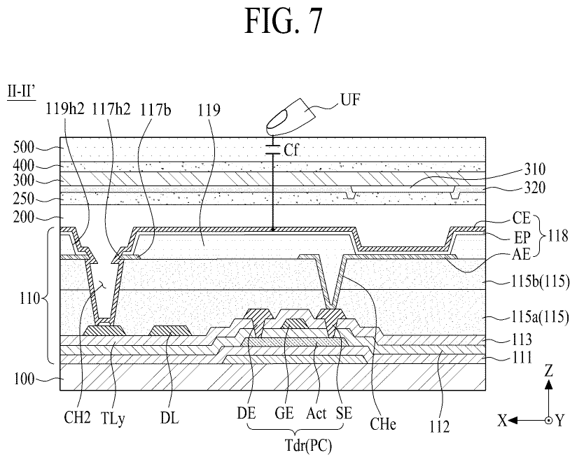

FIG. 7 is a cross-sectional view taken along line II-II′ illustrated in FIG. 4.

Particularly, FIG. 7 is a diagram illustrating an electrical connection structure of a plurality of second touch lines and a cathode electrode according to an embodiment of the present disclosure. In the following description, therefore, descriptions of the other elements except for the electrical connection structure of a plurality of second touch lines and a cathode electrode can be substantially a same as the description with reference to FIGS. 2 and 3, and thus, repeated descriptions thereof are omitted or briefly provided. Accordingly, the descriptions with reference to FIGS. 2 and 3 can be included in descriptions of FIG. 7.

Referring to FIGS. 4 and 7, each of the plurality of second touch lines TLy according to an embodiment of the present disclosure can be disposed on a same layer as the plurality of data lines DL or can be made of a same material as the plurality of data lines DL. The plurality of second touch lines TLy can be disposed parallel to the plurality of data lines DL.

Each of the plurality of second touch lines TLy according to an embodiment of the present disclosure can be formed (or disposed) over the interlayer insulating film 113 and covered by an overcoat layer 115. Each of the plurality of second touch lines TLy can be directly connected to the cathode electrode CE. For example, each of the plurality of second touch lines TLy can be electrically connected to the cathode electrode CE through the one or more second line contact holes CH2. The cathode electrode CE can be directly connected to each of the plurality of second touch lines TLy through the one or more second line contact holes CH2.

The one or more second line contact holes CH2 according to an embodiment can be formed to penetrate the overcoat layer 115 to expose a portion of each of the plurality of second touch lines TLy. The one or more second line contact holes CH2 can be formed to penetrate the overcoat layer 115 overlapping each of the plurality of second touch lines TLy. For example, the one or more second line contact holes CH2 can be formed by an etching process (or an over-etching process) on the overcoat layer 115 using a second mask metal pattern 117b having one or more second hollow holes 117h2 as a mask. For example, the second mask metal pattern 117b can be formed (or disposed) together with the anode electrode AE on the overcoat layer 115 overlapping each of the plurality of second touch lines TLy.

The one or more second line contact holes CH2 can be formed to penetrate the overcoat layer 115 by an etching process (or over-etching process) over the overcoat layer 115 overlapping the one or more second hollow holes 117h2 of the second mask metal pattern 117b. In addition, the bank 119 can include one or more second opening holes 119h2 overlapping the one or more second line contact holes CH2.

The light emitting portion EP formed (or deposited) on the one or more of the second line contact holes CH2 can be disconnected by an undercut region (or an eaves region) between each of the second mask metal patterns 117b and the overcoat layer 115 (or the second overcoat layer 115b). In addition, the cathode electrode CE formed (or deposited) on the one or more of the second line contact holes CH2 can be formed (or deposited) along the second opening hole 119h2 of the bank 119, the second hollow hole 117h2 of the second mask metal pattern 117b, and an inner surface (or sidewall) of the one or more of the second line contact holes CH2, thereby directly contacting (or connecting) with each of the plurality of second touch lines TLy.

Accordingly, the cathode electrode CE can receive the cathode voltage through each of the plurality of second touch lines TLy in the display driving period, and can receive the touch driving signal through each of the plurality of second touch lines TLy in the touch driving period.

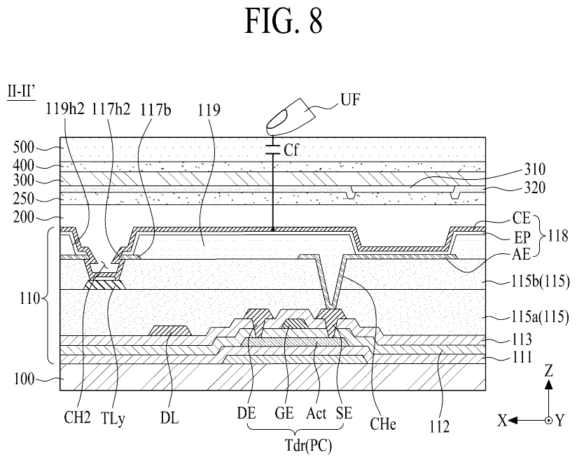

FIG. 8 is another cross-sectional view taken along line II-II′ illustrated in FIG. 4.

Particularly, FIG. 8 is a diagram illustrating an electrical connection structure of a plurality of second touch lines and a cathode electrode according to an embodiment of the present disclosure. In the following description, therefore, descriptions of the other elements except for the electrical connection structure of a plurality of second touch lines and a cathode electrode can be substantially a same as the description with reference to FIGS. 2 and 3, and thus, repeated descriptions thereof are omitted or briefly provided. Accordingly, the descriptions with reference to FIGS. 2 and 3 can be included in descriptions of FIG. 8.

Referring to FIGS. 4 and 8, the each of the plurality of second touch lines TLy according to another embodiment of the present disclosure can be formed (or disposed) in a different layer from each of the plurality of gate lines GL and each of the plurality of data lines DL. Each of the plurality of second touch lines TLy can be disposed in parallel with the plurality of data lines DL.

Each of the plurality of second touch lines TLy can be embedded within the overcoat layer 115. Each of the plurality of second touch lines TLy can be disposed (or interposed) between the first overcoat layer 115a and the second overcoat layer 115b.

Each of the plurality of second touch lines TLy can be formed (or disposed) over the first overcoat layer 115a and covered by the second overcoat layer 115b. Each of the plurality of second touch lines TLy can be directly connected to the cathode electrode CE. For example, each of the plurality of second touch lines TLy can be electrically connected to the cathode electrode CE through the one or more second line contact holes CH2. The cathode electrode CE can be directly connected to each of the plurality of second touch lines TLy through the one or more second line contact holes CH2.

The one or more second line contact holes CH2 according to another embodiment can be formed to penetrate the second overcoat layer 115b of the overcoat layer 115 to expose a portion of each of the plurality of second touch lines TLy. The one or more second line contact holes CH2 can be formed to penetrate the second overcoat layer 115b overlapping each of the plurality of second touch lines TLy. For example, the one or more second line contact holes CH2 can be formed by an etching process (or an over-etching process) on the second overcoat layer 115b using a second mask metal pattern 117b having one or more second hollow holes 117h2 as a mask. For example, the second mask metal pattern 117b can be formed (or disposed) together with an anode electrode AE on an overcoat layer 115 overlapping each of a plurality of second touch lines TLy.

The one or more second line contact holes CH2 can be formed to penetrate the first overcoat layer 115a by an etching process (or over-etching process) for the first overcoat layer 115a overlapping one or more second hollow holes (117h2) of the second mask metal pattern 117b. In addition, the bank (119) can include one or more second opening holes (119h2) overlapping one or more second line contact holes CH2.

The light emitting portion (EP) formed (or deposited) on one or more of the second line contact holes CH2 can be disconnected by an undercut region (or a ridge region) between each of the second mask metal patterns 117b and the second overcoat layer 115b. In addition, the cathode electrode CE formed (or deposited) on the one or more of the second line contact holes CH2 can be formed (or deposited) along the second opening hole 119h2 of the bank 119, the second hollow hole 117h2 of the second mask metal pattern 117b, and an inner surface (or sidewall) of the one or more of the second line contact holes CH2, thereby directly contacting (or connecting) with each of the plurality of second touch lines TLy.

Accordingly, the cathode electrode CE can receive the cathode voltage through each of the plurality of second touch lines TLy in the display driving period, and can receive the touch driving signal through each of the plurality of second touch lines TLy in the touch driving period.

Referring to FIGS. 7 and 8, in a touch driving period, when the touch driving signal is applied to the plurality of second touch lines TLy and a user's finger UF is in direct contact (or touch) with the cover window 500, a finger capacitance Cf is formed between the user's finger UF and the cathode electrode CE, and as the finger capacitance Cf is formed, a current can be generated in a transition period of the first touch driving signal applied to the second touch lines TLy corresponding to a touch area of the user's finger UF and flow to the second touch lines TLy close to the touch area of the user's finger UF. Accordingly, the driving circuit part can sense the current flowing through the second touch lines TLy corresponding to the touch area of the user's finger UF and calculate a Y-coordinate corresponding to a position of the second touch lines TLy where the current is generated of the plurality of second touch lines TLy.

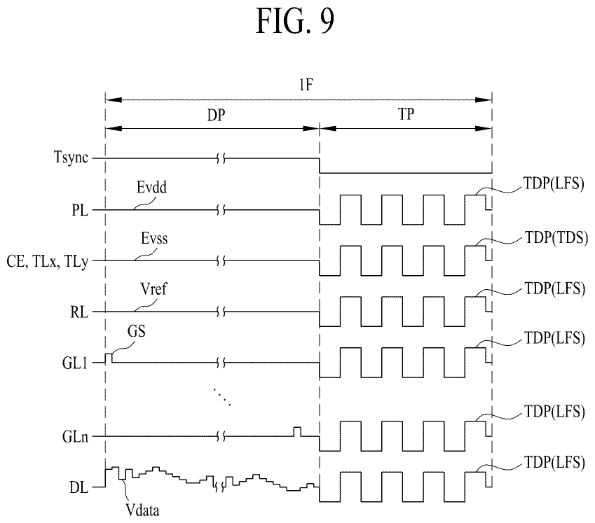

FIG. 9 is a diagram illustrating a display driving period and a touch driving period of a display apparatus according to an embodiment of the present disclosure.

Referring to FIG. 9, the display apparatus according to an embodiment of the present disclosure can be configured to display an image in units of frame periods.

One frame period 1F can be divided (or time-divided) into a display driving period DP and a touch driving period TP. The display driving period DP and the touch driving period TP can be classified by a touch synchronization signal Tsync based on a vertical synchronization signal. For example, the touch synchronization signal Tsync can have a high period corresponding to the display driving period DP and a low period corresponding to the touch driving period TP.

The display driving period DP can be a period for displaying an image on the display panel. The touch driving period TP can be a period for sensing a user touch. The touch driving period TP can be shorter than the display driving period DP, but is not limited thereto.

In the display driving period DP, a gate signal GS can be applied to the gate line GL, a data signal Vdata can be applied to the data line DL to be synchronized with the gate signal GS, a pixel driving voltage Evdd can be applied to the pixel driving voltage line PL, a reference voltage Vref can be applied to the reference line RL, and a cathode voltage Evss can be applied to the first touch line TLx and the second touch line TLy. Accordingly, the pixel circuit PC configured in the sub-pixel SP described with reference to FIGS. 1 and 2 supplies a data current corresponding to the data signal Vdata to the light emitting portion EP, and the light emitting portion EP can emit light with a brightness corresponding to the data current flowing from the first touch line TLx to the cathode electrode CE. For example, a voltage level of the pixel driving voltage Evdd can be 24 V and a voltage level of the cathode voltage Evss can be 0 V, but is not limited thereto.

In the touch driving period TP, a touch driving signal TDS can be applied to the first touch line TLx and the second touch line TLy. The touch driving signal TDS can have a plurality of driving pulses TDP. For example, when a user touches, due to a finger capacitance between the cathode electrode CE and a user's finger, a current is generated or flows in a transition period of the plurality of driving pulses TDP applied to the first touch line TLx and the second touch line TLy, and thus, the current can be sensed by the driving circuit part 30.

In the touch driving period TP, a load reduction signal LFS can be applied to each of the data line DL and the gate lines GL1 to GLn. The load reduction signal LFS can be a same as the touch driving signal TDS. The load reduction signal LFS is applied to the data line DL and the gate lines GL1 to GLn simultaneously, and since the cathode electrode CE, the data line DL, and the gate lines GL1 to GLn have a same voltage level, a voltage difference does not occur between the cathode electrode CE, the data line DL, and the gate lines GL1 to GLn, and since no capacitance is generated (or formed), power consumption of the display apparatus can be reduced, and the sensitivity of touch sensing can be improved.

Furthermore, in the touch driving period TP, the load reduction signal LFS can also be applied to the plurality of pixel driving voltage lines PL and the plurality of reference lines RL. For example, in the touch driving period TP, the load reduction signal LFS can be applied to all pixel driving lines DL, GL, PL, and RL simultaneously.

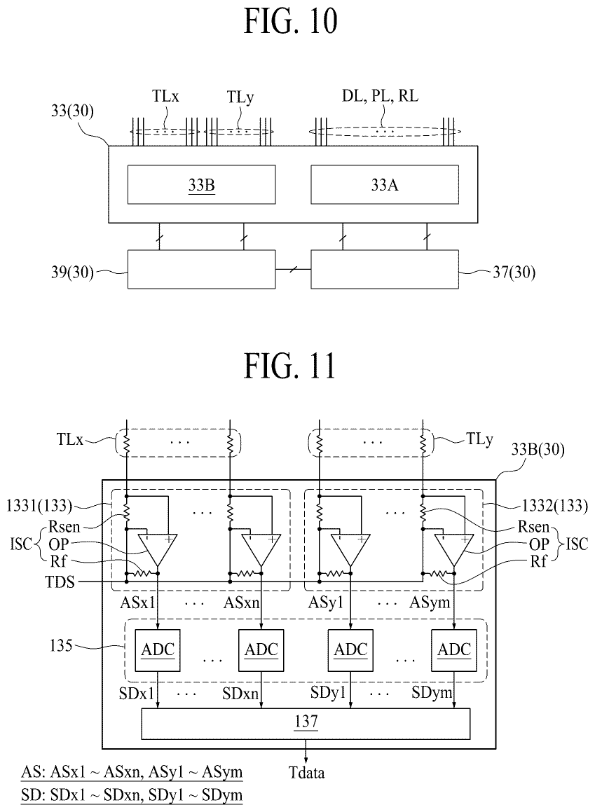

FIG. 10 is a diagram illustrating a data driving integrated circuit, a timing control part, and a power generating integrated circuit illustrated in FIG. 1.

Referring to FIGS. 9 and 10, in the display apparatus according to an embodiment of the present disclosure, the plurality of first touch lines TLx and the plurality of second touch lines TLy can be used (or driven) as touch sensing electrodes (or touch sensing lines), which is called an in-cell touch structure. Since the display apparatus according to an embodiment of the present disclosure does not have separate touch electrodes, the thickness of the display panel can be reduced.

The display apparatus or the driving circuit part 30 according to an embodiment of the present disclosure can perform touch driving and touch sensing based on a current sensing method.

In the touch driving period TP, when the touch driving signal is applied to the plurality of first touch lines TLx and the plurality of second touch lines TLy, and a user's finger UF is in direct contact (or touch) with the cover window 500, a finger capacitance Cf is formed between the user's finger UF and the cathode electrode CE, and as the finger capacitance Cf is formed, a current can be generated in a transition period of the touch driving signal applied to the plurality of first touch lines TLx and the plurality of second touch lines TLy corresponding to a touch area of the user's finger UF and flow to the first touch line TLx and the second touch lines TLy close to the touch area of the user's finger UF. The driving circuit part 30 can sense the current flowing through the first touch line TLx and the second touch lines TLy corresponding to the touch region of the user's finger UF to determine whether a touch is present or to determine touch coordinates.

In the driving circuit part 30 according to an embodiment of the present disclosure, a data driving integrated circuit 33 can include a data driving circuit 33A and a touch driving circuit 33B.

The data driving circuit 33A can be a data integrated circuit for driving data lines DL. For example, the data driving circuit 33A can be a data integrated circuit for driving each of the data lines DL and reference lines RL. The touch driving circuit 33B can be a touch integrated circuit for touch sensing. The touch driving circuit 33B can be a read-out integrated circuit. Each of the data driving circuit 33A and the touch driving circuit 33B can be implemented as separate integrated circuits.

The data driving circuit 33A can be connected to the plurality of data lines DL. The data driving circuit 33A can be connected to the plurality of reference lines RL.

The data driving circuit 33A can be configured to receive pixel data and a data control signal provided from a timing control part 37 in the display driving period DP, convert the pixel data into an analog pixel-based data signal (or pixel-by-pixel analog data) according to the data control signal, and supply the analog pixel-based data signal to a corresponding data line DL. The data driving circuit 33A can be configured to receive the pixel driving voltage Evdd and the reference voltage Vref provided from a power generation integrated circuit 39, and supply the pixel driving voltage Evdd to the plurality of pixel driving voltage lines PL and supply the reference voltage Vref to the plurality of reference lines RL in the display driving period DP.

The data driving circuit 33A according to an embodiment can be configured to maintain each of the plurality of data lines DL, the plurality of gate lines GL, the plurality of pixel driving voltage lines PL, and the plurality of reference lines RL in a high impedance state during the touch driving period TP. For example, the data driving circuit 33A can be configured to electrically float each of the plurality of data lines DL, the plurality of gate lines GL, the plurality of pixel driving voltage lines PL, and the plurality of reference lines RL in the touch driving period TP.

The data driving circuit 33A according to another embodiment can be configured to supply the load reduction signal LFS provided from the power generating integrated circuit 39 to each of the plurality of data lines DL, the plurality of gate lines GL, the plurality of pixel driving voltage lines PL, and the plurality of reference lines RL in the touch driving period TP.

The touch driving circuit 33B can be connected to the plurality of first touch lines TLx and the plurality of second touch lines TLy.

The touch driving circuit 33B can be configured to supply the cathode voltage Evss provided from the power generating integrated circuit 39 to the plurality of first touch lines TLx and the plurality of second touch lines TLy in the display driving period DP. Accordingly, in the display driving period DP, the cathode voltage Evss can be supplied to the cathode electrode CE through the plurality of first touch lines TLx and the plurality of second touch lines TLy.

The touch driving circuit 33B can be configured to supply the touch driving signal TDS provided from the power generating integrated circuit 39 to the plurality of first touch lines TLx and the plurality of second touch lines TLy, and to sense current flowing through each of the plurality of first touch lines TLx and the plurality of second touch lines TLy based on a user touch, thereby determining whether a touch is present or determining touch coordinates.

The touch driving circuit 33B can provide touch coordinate data based on the user touch to the timing control part 37 or to a host driving system of the display apparatus in the touch driving period TP. Accordingly, the timing control part 37 or the host driving system can execute one or more application corresponding to the touch coordinate data.

FIG. 11 is a diagram illustrating a touch driving circuit illustrated in FIG. 10.

Referring to FIGS. 9 to 11, a touch driving circuit 33B according to an embodiment of the present disclosure can include a current sensing unit 133, a digital conversion unit 135, and a touch control unit 137.

The current sensing unit 133 can be configured to output a plurality of analog signals AS corresponding to a change in current flowing through each of the plurality of first touch lines TLx and the plurality of second metal lines TLy.

The current sensing unit 133 according to an embodiment can include a first current sensing unit 1331 and a second current sensing unit 1332.

The first current sensing unit 1331 can be configured to be electrically connected to the plurality of first touch lines TLx. The first current sensing unit 1331 can be configured to supply the cathode voltage Evss or the touch driving signal TDS provided from the power generating integrated circuit 39 to the plurality of first touch lines TLx. For example, in the display driving period DP, the cathode voltage Evss provided from the power generating integrated circuit 39 can be supplied to the cathode electrode CE through the first current sensing unit 1331 and the plurality of first touch lines TLx. In addition, in the touch driving period TP, the touch driving signal TDS provided from the power generating integrated circuit 39 can be supplied to the cathode electrode CE through the first current sensing unit 1331 and the plurality of first touch lines TLx.

The first current sensing unit 1331 can be configured to output a plurality of first analog signals ASx1 to ASxn corresponding to a change in current flowing through each of the plurality of first touch lines TLx based on a user touch in the touch driving period TP.

The second current sensing unit 1332 can be configured to be electrically connected to the plurality of second touch lines TLy. The second current sensing unit 1332 can be configured to supply the cathode voltage Evss or the touch driving signal TDS provided from the power generating integrated circuit 39 to the plurality of second touch lines TLy. For example, in the display driving period DP, the cathode voltage Evss provided from the power generating integrated circuit 39 can be supplied to the cathode electrode CE through the second current sensing unit 1332 and the plurality of second touch lines TLy. In addition, in the touch driving period TP, the touch driving signal TDS provided from the power generating integrated circuit 39 can be supplied to the cathode electrode CE through the second current sensing unit 1332 and the plurality of second touch lines TLy.

The second current sensing unit 1332 can be configured to output a plurality of second analog signals ASy1 to ASym corresponding to a change in current flowing through each of the plurality of second touch lines TLy based on a user touch in the touch driving period TP.

The current sensing unit 133 (or the first and second current sensing units 1331 and 1332) according to an embodiment can include a plurality of current sensing circuits ISC.

Each of the plurality of current sensing circuits ISC can include a sensing resistor Rsen, an operational amplifier OP, and a feedback resistor Rf.

The sensing resistor Rsen can be electrically connected to a corresponding line of the plurality of first touch lines TLx and the plurality of second touch lines TLy. For example, the sensing resistor Rsen can be a shunt resistor.

According to an embodiment, in the current sensing circuit ISC configured at the first current sensing unit 1331, the sensing resistor Rsen can be electrically connected to a corresponding first touch line of the plurality of first touch lines TLx. For example, one end of the sensing resistor Rsen can be electrically connected to an output terminal of the cathode voltage Evss among output terminals of the power generating integrated circuit 39, and the other end of the sensing resistor Rsen can be electrically connected to a corresponding first touch line among the plurality of first touch lines TLx. Accordingly, in the display driving period DP, the cathode voltage Evss supplied from the power generating integrated circuit 39 to the sensing resistor Rsen can be supplied to the first touch line TLx through the sensing resistor Rsen. Similarly, in the touch driving period TP, the touch driving signal TDS supplied from the power generating integrated circuit 39 to the sensing resistor Rsen can be supplied to the first touch line TLx through the sensing resistor Rsen.

According to an embodiment, in the current sensing circuit ISC configured at the second current sensing unit 1332, the sensing resistor Rsen can be electrically connected to a corresponding second touch line of the plurality of second touch lines TLy. For example, one end (or a first terminal) of the sensing resistor Rsen can be electrically connected to a corresponding second touch line of the plurality of second touch lines TLy, and the other end (or a second terminal) of the sensing resistor Rsen can be electrically connected to an output terminal of the cathode voltage Evss among the output terminals of the power generating integrated circuit 39. Accordingly, in the touch driving period TP, the cathode voltage Evss supplied from the power generating integrated circuit 39 to the sensing resistor Rsen can be supplied to the second touch line TLy through the sensing resistor Rsen. Similarly, in the touch driving period TP, the touch driving signal TDS supplied from the power generating integrated circuit 39 to the sensing resistor Rsen can be supplied to the second touch line TLy through the sensing resistor Rsen.

According to an embodiment, the sensing resistor Rsen configured at the first current sensing unit 1331 and the sensing resistor Rsen configured at the second current sensing unit 1332 can have different resistance values, but is not limited thereto, and can have a same resistance value.

The operational amplifier OP can be configured to be electrically connected to both ends of the sensing resistor Rsen and to output an analog signal AS corresponding to a change in current flowing through the sensing resistor Rsen. For example, the operational amplifier OP can include a non-inverting terminal (+) connected to one end (or the first terminal) of the sensing resistor Rsen, and an inverting terminal (−) connected to the other end (or the second terminal) of the sensing resistor Rsen. For example, the operational amplifier OP can be a differential amplifier, but is not limited thereto. An output terminal of the operational amplifier OP can be connected to the digital conversion unit 135.

The feedback resistor Rf can be connected between the inverting terminal (−) and the output terminal of the operational amplifier OP. The feedback resistor Rf can have a different resistance value from the sensing resistor Rsen.

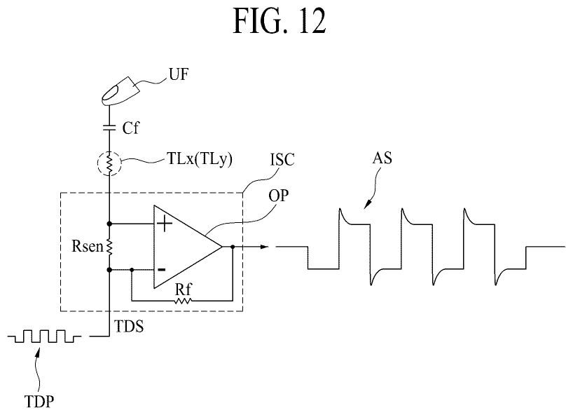

As illustrated in FIG. 12, in the touch driving period TP, the operational amplifier OP configured at the first current sensing unit 1331 can be configured to output the analog signal AS corresponding to the current generated in a transition period of the plurality of driving pulses TDP applied to the first touch line TLx due to the finger capacitance Cf formed based on a touch of the user's finger UF. For example, in the touch driving period TP, the operational amplifier OP configured at the first current sensing unit 1331 can be configured to output the analog signal AS corresponding to the current flowing through the first touch line TLx based on an input voltage determined by the voltage division between the sensing resistor Rsen and the feedback resistor Rf. For example, in the touch driving period TP, the operational amplifier OP configured at the first current sensing unit 1331 can be configured to output the first analog signal ASx1 to ASxn corresponding to current flowing through a corresponding first touch line among the plurality of first touch lines TLx.

As illustrated in FIG. 12, in the touch driving period TP, the operational amplifier OP configured at the second current sensing unit 1332 can be configured to output the analog signal AS corresponding to the current generated through the transition period of the plurality of driving pulses TDP applied to the second touch line TLy due to the finger capacitance Cf formed based on a touch of the user's finger UF. For example, in the touch driving period TP, the operational amplifier OP configured at the second current sensing unit 1332 can be configured to output the analog signal AS corresponding to the current flowing through the second touch line TLy based on an input voltage determined by the voltage division between the sensing resistor Rsen and the feedback resistor Rf. For example, in the touch driving period TP, the operational amplifier OP configured at the second current sensing unit 1332 can be configured to output the second analog signal ASy1 to ASym corresponding to current flowing through a corresponding second touch line among the plurality of second touch lines TLy.

The digital conversion unit 135 can be configured to be electrically connected to the output terminal of the current sensing unit 133. The digital conversion unit 135 can be electrically connected to the output terminal of the operational amplifier OP of each of the plurality of current sensing circuits ISC configured at the current sensing unit 133.

The digital conversion unit 135 can be configured to output a plurality of sensing data SD corresponding to each of the plurality of analog signals AS output from the current sensing unit 133. The digital conversion unit 135 can be configured to output the plurality of sensing data SD corresponding to each of the plurality of analog signals AS output from each of the plurality of operational amplifiers OP.

The digital conversion unit 135 according to an embodiment can include a plurality of analog-to-digital conversion circuits ADC.

The plurality of analog-to-digital conversion circuits ADC can be configured to be individually connected to the plurality of current sensing circuits ISC configured at the current sensing unit 133. Each of the plurality of analog-to-digital conversion circuits ADC can be individually connected to the plurality of operational amplifiers OP configured at the current sensing unit 133.

Each of the plurality of analog-to-digital conversion circuits ADC can convert the analog signal AS supplied from a corresponding operational amplifier OP among the plurality of operational amplifiers OP into a digital signal to generate or output sensing data SDx1 to SDxn and SDy1 to SDym. For example, each of the plurality of analog-to-digital conversion circuits ADC connected to each of the plurality of operational amplifiers OP configured at the first current sensing unit 1331 can convert the analog signal AS supplied from the operational amplifier OP into a digital signal to generate or output the plurality of first sensing data SDx1 to SDxn. For example, each of the plurality of analog-to-digital conversion circuits ADC connected to each of the plurality of operational amplifiers OP configured at the second current sensing unit 1332 can convert the analog signal AS supplied from the operational amplifier OP into a digital signal to generate or output the plurality of second sensing data SDy1 to SDym.

The touch control unit 137 can be configured to determine whether a touch is present or to determine touch coordinates based on the plurality of sensing data SDx1 to SDxn and SDy1 to SDym provided from the digital conversion unit 135. For example, the touch control unit 137 can compare the plurality of sensing data SDx1 to SDxn and SDy1 to SDym with a set threshold value, and can calculate the touch presence or touch coordinates by using sensing data greater than the threshold value. For example, the touch control unit 137 can calculate an X-coordinate corresponding to the position of the first touch line TLx where sensing data greater than the threshold value is generated among the plurality of first sensing data SDx1 to SDxn provided from the first current sensing unit 1331. In addition, the touch control unit 137 can calculate a Y-coordinate corresponding to the position of the second touch line TLy where sensing data greater than the threshold value is generated among the plurality of second sensing data SDy1 to SDym provided from the second current sensing unit 1332. Additionally, the touch control unit 137 can calculate the number of touch points from the calculated touch coordinate values, or calculate the number of touches by counting the number of touch points calculated within a unit time, or calculate the duration of touch within a unit time.

The touch control unit 137 can provide touch coordinate data based on the user touch to the timing control part 37 or to the host driving system of the display apparatus. Accordingly, the timing control part 37 or the host driving system can execute one or more application corresponding to the touch coordinate data.

As described above, the display apparatus according to embodiments of the present disclosure can include the plurality of first touch lines TLx and the plurality of second touch lines TLy electrically connected to the cathode electrode CE, thereby sensing a user touch through current flowing through each of the plurality of first touch lines TLx and the plurality of second touch lines TLy, and can have a thin thickness because a separate touch panel is not attached due to the in-cell touch structure.

The display apparatus according to embodiments of the present disclosure can be applied to all electronic devices. For example, the display apparatus according to an embodiment of the present disclosure can be applied to mobile apparatuses, video phones, smart watches, watch phones, wearable apparatuses, foldable apparatuses, rollable apparatuses, bendable apparatuses, flexible apparatuses, curved apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, TVs, wall paper display apparatuses, signage apparatuses, game machines, notebook computers, monitors, cameras, camcorders, and home appliances, or the like.

It will be apparent to those skilled in the art that various modifications and variations can be made in the present disclosure without departing from the spirit or scope of the disclosures. Thus, it is intended that the present disclosure covers the modifications and variations of this disclosure provided that within the scope of the claims and their equivalents.

What is claimed is:

1. A display apparatus comprising:
a substrate having a display area and a non-display area adjacent to the display area;
a pixel circuit layer including a plurality of pixel circuits disposed at the display area of the substrate;
an overcoat layer covering the pixel circuit layer; and
a light emitting device layer disposed on the overcoat layer and connected to the plurality of pixel circuits,
wherein the light emitting device layer comprises:
a plurality of anode electrodes disposed on the overcoat layer and connected to the plurality of pixel circuits;
a light emitting portion disposed on the plurality of anode electrodes; and
a cathode electrode disposed in the display area and electrically connected to the light emitting portion, and
wherein the pixel circuit layer comprises:
a plurality of gate lines disposed in a first direction on the substrate and connected to corresponding pixel circuits of the plurality of pixel circuits;
a plurality of data lines disposed in a second direction intersecting the first direction on the substrate, and connected to corresponding pixel circuits of the plurality of pixel circuits;
a plurality of pixel driving voltage lines disposed in the second direction on the substrate and connected to corresponding pixel circuits of the plurality of pixel circuits;
a plurality of first touch lines disposed in the first direction on the substrate and electrically connected to the cathode electrode; and
a plurality of second touch lines disposed in the second direction on the substrate and electrically connected to the cathode electrode.

2. The display apparatus of claim 1, wherein:
the cathode electrode receives a cathode voltage in a display driving period and receives a touch driving signal in a touch driving period, and
the plurality of first touch lines and the plurality of second touch lines receive the touch driving signal in the touch driving period.

3. The display apparatus of claim 2, wherein each of the plurality of gate lines, the plurality of data lines, and the plurality of pixel driving voltage lines is maintained in a high impedance state in the touch driving period.

4. The display apparatus of claim 1, wherein the cathode electrode is directly connected to each of the plurality of first touch lines through one or more first line contact holes, and is directly connected to each of the plurality of second touch lines through one or more second line contact holes.

5. The display apparatus of claim 1, wherein:
each of the plurality of first touch lines is disposed on a same layer as the plurality of gate lines and is electrically connected to the cathode electrode through one or more first line contact holes, and
each of the plurality of second touch lines is disposed on a same layer as the plurality of data lines and is electrically connected to the cathode electrode through one or more second line contact holes.

6. The display apparatus of claim 5, wherein:
each of the plurality of first touch lines is electrically connected to the cathode electrode through an intermediate metal pattern, and
the intermediate metal pattern is disposed on a same layer as the plurality of data lines.

7. The display apparatus of claim 1, wherein:
the overcoat layer comprises:
a first overcoat layer covering the pixel circuit layer; and
a second overcoat layer covering the first overcoat layer,
each of the plurality of first touch lines is composed of a same material as the plurality of gate lines and is electrically connected to the cathode electrode through one or more first line contact holes, and
each of the plurality of second touch lines is disposed between the first overcoat layer and the second overcoat layer and is electrically connected to the cathode electrode through one or more second line contact holes.

8. The display apparatus of claim 1, wherein:
each of the plurality of first touch lines is electrically connected to the cathode electrode through one or more intermediate metal patterns, and
the one or more intermediate metal patterns are composed of a same material as the plurality of data lines.

9. The display apparatus of claim 2, wherein:
each of the plurality of gate lines, the plurality of data lines, and the plurality of pixel driving voltage lines receives a load reduction signal synchronized with the touch driving signal in the touch sensing period, and
the load reduction signal and the touch driving signal include a same frequency and a same voltage amplitude.

10. The display apparatus of claim 2, further comprising a driving circuit part to sense a user touch through each of the plurality of first touch lines and each of the plurality of second touch lines in the touch driving period.

11. The display apparatus of claim 10, wherein:
the driving circuit part includes a touch driving circuit configured to sense a current flowing through each of the plurality of first touch lines and each of the plurality of second touch lines to determine whether a touch is present or to determine touch coordinates, in the touch driving period.

12. The display apparatus of claim 10, wherein the driving circuit part includes a touch driving circuit, and
wherein the touch driving circuit comprises:
a current sensing unit configured to output a plurality of analog signals corresponding to a change in current flowing through each of the plurality of first touch lines and the plurality of second touch lines;
a digital conversion unit configured to output a plurality of sensing data corresponding to each of the plurality of analog signals output from the current sensing unit; and
a touch control unit configured to determine whether a touch is present or to determine touch coordinates based on the plurality of sensing data supplied from the digital conversion unit.

13. The display apparatus of claim 12, wherein:
the current sensing unit includes a plurality of current sensing circuits, and
each of the plurality of current sensing circuits comprises:
a sensing resistor connected to a corresponding touch line among the plurality of first touch lines and the plurality of second touch lines; and
an operational amplifier electrically connected to both ends of the sensing resistor and configured to output an analog signal corresponding to a change in current flowing through the sensing resistor.

14. The display apparatus of claim 2, further comprising:
a plurality of driving integrated circuits electrically connected to the plurality of data lines, the plurality of pixel driving voltage lines, the plurality of first touch lines, and the plurality of second touch lines; and
a power generating integrated circuit configured to generate the cathode voltage, the pixel driving voltage, and the touch driving signal,
wherein the power generating integrated circuit supplies the cathode voltage and the pixel driving voltage to the plurality of driving integrated circuits in the display driving period, and
wherein the power generating integrated circuit supplies the touch driving signal to the plurality of driving integrated circuits in the touch driving period.

15. The display apparatus of claim 14, wherein the power generating integrated circuit is configured to generate the touch driving signal having a plurality of touch driving pulses by modulating the cathode voltage.

16. The display apparatus of claim 4, further comprising:
a plurality of driving integrated circuits electrically connected to the plurality of data lines, the plurality of pixel driving voltage lines, the plurality of first touch lines, and the plurality of second touch lines; and
a power generating integrated circuit configured to generate the cathode voltage, the pixel driving voltage, and the touch driving signal,
wherein the power generating integrated circuit supplies the cathode voltage and the pixel driving voltage to the plurality of driving integrated circuits in the display driving period, or the power generating integrated circuit supplies the touch driving signal to the plurality of driving integrated circuits in the touch driving period.

17. The display apparatus of claim 2, further comprising:
an encapsulation layer covering the light emitting device layer; and
a cover window disposed on the encapsulation layer.

18. The display apparatus of claim 17, further comprising a touch driving circuit configured to sense a user touch on the cover window through each of the plurality of first touch lines and each of the plurality of second touch lines to determine whether a touch is present or to determine touch coordinates, in the touch driving period.

19. A display apparatus comprising:
a substrate having a display area and a non-display area;
a pixel circuit layer including a plurality of pixel circuits disposed at the display area of the substrate;
an overcoat layer covering the pixel circuit layer; and
a light emitting device layer disposed on the overcoat layer and connected to the plurality of pixel circuits,
wherein the light emitting device layer comprises a cathode electrode disposed in the display area, and
wherein the pixel circuit layer comprises:
a plurality of gate lines disposed in a first direction on the substrate and connected to corresponding pixel circuits of the plurality of pixel circuits;
a plurality of data lines disposed in a second direction intersecting the first direction on the substrate, and connected to corresponding pixel circuits of the plurality of pixel circuits;
a plurality of pixel driving voltage lines disposed in the second direction on the substrate and connected to corresponding pixel circuits of the plurality of pixel circuits;
a plurality of first touch lines disposed in the first direction on the substrate and electrically connected to the cathode electrode; and
a plurality of second touch lines disposed in the second direction on the substrate and electrically connected to the cathode electrode.
